(19) United States
(12) Patent Application Publication
(10) Pub. No.: US 2026/0020481 A1
(43) Pub. Date: Jan. 15, 2026

(54) DISPLAY PANEL, METHOD FOR MANUFACTURING DISPLAY PANEL, AND ELECTRONIC DEVICE

(71) Applicants: Hefei Visionox Technology Co., Ltd., Hefei (CN); Visionox Technology Inc., Kunshan (CN)

(72) Inventors: Wenyan ZHAO, Hefei (CN); Yang SHAO, Kunshan (CN); Yuan YAO, Hefei (CN); Lu YIN, Hefei (CN); Haohan ZHANG, Hefei (CN)

(73) Assignees: Hefei Visionox Technology Co., Ltd., Hefei (CN); Visionox Technology Inc., Kunshan (CN)

(21) Appl. No.: 19/264,874

(22) Filed: Jul. 10, 2025

(30) Foreign Application Priority Data
Jul. 12, 2024 (CN) 202410940554.3

(51) Int. Cl. H10K 59/80; H10K 59/12

(52) U.S. Cl. CPC H10K 59/873; H10K 59/1201

(57) ABSTRACT

The present application provides a display panel, a method for manufacturing a display panel, and an electronic device. In the display panel having at least an isolation structure, a first encapsulation layer covering a non-active area is fabricated while fabricating a third light-emitting device and its corresponding encapsulation unit, and the encapsulation effect of the display panel can be guaranteed. Furthermore, in the display panel, the method for manufacturing a display panel, and the electronic device provided in the present application, the first encapsulation layer is formed simultaneously with the third encapsulation unit corresponding to the third light-emitting device fabricated last, and it is possible to prevent the etching operation on the light-emitting device and the encapsulation unit fabricated later from affecting the first encapsulation layer in the non-active area, thereby ensuring the encapsulation reliability of the first encapsulation layer.

### CROSS-REFERENCE TO RELATED APPLICATIONS

The present application claims priority to the Chinese Patent Application No. 202410940554.3, filed on Jul. 12, 2024, and the entire contents of the aforementioned application are hereby incorporated by reference in its entirety.

### FIELD

The present application relates to the field of displays, and in particular to a display panel, a method for manufacturing a display panel, and an electronic device.

### BACKGROUND

Organic light-emitting diodes (OLEDs) and flat panel display devices based on technologies such as light-emitting diodes (LEDs) have been widely applied to various consumer electronics such as mobile phones, televisions, notebook computers and desktop computers and predominate in display devices thanks to their advantages such as high image quality, energy efficiency, slim design and a wide range of applications.

However, the process performance of conventional OLED display products needs to be improved.

### SUMMARY

In order to overcome the above-mentioned disadvantages of the prior art, an objective of the present application is to provide a display panel, including an active area and a non-active area at least partially surrounding the active area; and including:
a substrate;
an array functional layer located on one side of the substrate;
at least an isolation structure located on a side of the array functional layer away from the substrate;
at least an isolation opening defined in the active area;
at least a light-emitting device and at least a corresponding encapsulation unit, which are at least partially located in the isolation opening, the encapsulation unit being located on a side of the light-emitting device away from the substrate; and
a redundant light-emitting functional layer and a first encapsulation layer, which are stacked in the non-active area and on the side of the array functional layer away from the substrate.

In some embodiments, the at least a light-emitting device includes a plurality of light-emitting devices, the plurality of light-emitting devices including a first light-emitting device, a second light-emitting device and a third light-emitting device, light-emitting colors of the first light-emitting device, the second light-emitting device and the third light-emitting device being different from one another, and a light-emitting color of the redundant light-emitting functional layer being the same as one of the light-emitting colors of the light-emitting devices; and
the at least an encapsulation unit comprises a plurality of encapsulation units, the encapsulation units including a first encapsulation unit located on a side of the first light-emitting device away from the substrate, a second encapsulation unit located on a side of the second light-emitting device away from the substrate, and a third encapsulation unit located on a side of the third light-emitting device away from the substrate, and the first encapsulation layer corresponding to one of the encapsulation units which has a light-emitting color same to that of the redundant light-emitting functional layer.

In some embodiments, the first encapsulation layer is fabricated simultaneously with one of the encapsulation units which has a light-emitting color same to that of the redundant light-emitting functional layer.

In some embodiments, the first light-emitting device, the second light-emitting device, and the third light-emitting device are fabricated in sequence, the third light-emitting device being the last to be fabricated, the redundant light-emitting functional layer and the third light-emitting device have the same light-emitting color, and the first encapsulation layer is the same as the third encapsulation unit.

In one embodiment, the degree of etch damage of the first encapsulation layer and the third encapsulation unit is less than the degree of etch damage of the first encapsulation unit and the second encapsulation unit.

In one embodiment, a maximum thickness of the first encapsulation layer and the third encapsulation unit is greater than a maximum thickness of the first encapsulation unit and the second encapsulation unit.

In some embodiments, in the non-active area, the array functional layer includes a dam structure protruding in a direction away from the substrate, the dam structure at least partially surrounding the active area; and at least parts of the redundant light-emitting functional layer and the first encapsulation layer are located on a side of the dam structure away from the substrate.

In some embodiments, the display panel further includes a second encapsulation layer located on a side of the encapsulation unit and the isolation structure away from the substrate, and a third encapsulation layer located on a side of the second encapsulation layer away from the substrate.

In one embodiment, an orthographic projection of the second encapsulation layer on the substrate is located on a side, close to the active area, of an orthographic projection of the dam structure on the substrate.

In one embodiment, materials of the encapsulation unit, the first encapsulation layer and the third encapsulation layer include inorganic materials, and a material of the second encapsulation layer includes an organic material.

In some embodiments, the third encapsulation layer extends from a side of the dam structure close to the active area to a side of the dam structure away from the active area; and the first encapsulation layer located on the side of the dam structure away from the active area is in contact with the third encapsulation layer.

In some embodiments, an orthographic projection of an end of each of the redundant light-emitting functional layer and the first encapsulation layer away from the active area on the substrate is located within an orthographic projection of the third encapsulation layer on the substrate.

In some embodiments, the display panel includes at least two dam structures arranged in a direction away from the active area.

In some embodiments, the light-emitting device includes a first electrode, a light-emitting unit and a second electrode stacked in a direction away from the substrate, and the isolation structure has an electrical conductivity, the second electrode being electrically connected to the isolation structure.

In some embodiments, the isolation structure includes a support portion and a shielding portion located on a side of the support portion away from the substrate, an orthographic projection of the support portion on the substrate being located within an orthographic projection of the shielding portion on the substrate.

In one embodiment, an etching resistance of the support portion is weaker than an etching resistance of the shielding portion.

In one embodiment, a material of the support portion includes aluminum, and/or a material of the shielding portion includes titanium.

In some embodiments, the isolation structure further includes a receiving portion located between the support portion and the substrate.

In one embodiment, an orthographic projection of the receiving portion on the substrate is located within the orthographic projection of the shielding portion on the substrate.

In one embodiment, a material of the receiving portion includes molybdenum.

The present application also provides a display panel, including an active area and a non-active area at least partially surrounding the active area; and including:
a substrate;
an array functional layer located on one side of the substrate; and
a redundant light-emitting functional layer and a first encapsulation layer, which are located in the non-active area and on the side of the array functional layer away from the substrate and are stacked in a direction away from the substrate.

The present application also provides a method for manufacturing a display panel, the display panel including an active area and a non-active area at least partially surrounding the active area, the method including:
providing a substrate;
providing an array functional layer on one side of the substrate;
providing at least an isolation structure on a side of the array functional layer away from the substrate, and at least an isolation opening defined in the active area, the at least an isolation opening including a first isolation opening, a second isolation opening and a third isolation opening;
providing, in the first isolation opening, a first light-emitting device of a plurality of light-emitting devices and a first encapsulation unit located on a side of the first light-emitting device away from the substrate;
providing, in the second isolation opening, a second light-emitting device of the light-emitting devices and a second encapsulation unit located on a side of the second light-emitting device away from the substrate; and
providing, in the third isolation opening, a third light-emitting device of the light-emitting devices and a third encapsulation unit located on a side of the third light-emitting device away from the substrate, and providing a redundant light-emitting functional layer and a first encapsulation layer on a side of the dam structure away from the substrate.

In some embodiments, the step of providing, in the third isolation opening, a third light-emitting device of the light-emitting devices and a third encapsulation unit located on a side of the third light-emitting device away from the substrate, and providing a redundant light-emitting functional layer and a first encapsulation layer on a side of the dam structure away from the substrate includes:
providing a full-coverage light-emitting functional layer and encapsulation material layer from a side of the isolation structure away from the substrate;
providing an etch stop material covering the third isolation opening and the non-active area; and
etching the light-emitting functional layer and the encapsulation material layer to remove part of the light-emitting functional layer and the encapsulation material layer within the first isolation opening and the second isolation opening while retaining part of the light-emitting functional layer and the encapsulation material layer within the third isolation opening and in the non-active area, to form the third light-emitting device and the third encapsulation unit that are at least partially located in the third isolation opening, and the redundant light-emitting functional layer and the first encapsulation layer that are located in the non-active area.

In one embodiment, the light-emitting device includes at least a light-emitting device at least partially located in the isolation opening and at least an encapsulation unit located on a side of the light-emitting device away from the substrate.

In some embodiments, the step of providing, in the first isolation opening, a first light-emitting device of a plurality of light-emitting devices and a first encapsulation unit located on a side of the first light-emitting device away from the substrate includes:
providing a full-coverage light-emitting functional layer and encapsulation material layer from a side of the isolation structure away from the substrate;
providing an etch stop material covering the first isolation opening; and
etching the light-emitting functional layer and the encapsulation material layer to remove part of the light-emitting functional layer and the encapsulation material layer within the second isolation opening, within the third isolation opening and in the non-active area while retaining part of the light-emitting functional layer and the encapsulation material layer within the first isolation opening, to form the first light-emitting device and the first encapsulation unit that are at least partially located in the first isolation opening; and the step of providing, in the second isolation opening, a second light-emitting device of the light-emitting devices and a second encapsulation unit located on a side of the second light-emitting device away from the substrate includes:
providing a full-coverage light-emitting functional layer and encapsulation material layer from a side of the isolation structure away from the substrate;
providing an etch stop material covering the second isolation opening; and
etching the light-emitting functional layer and the encapsulation material layer to remove part of the light-emitting functional layer and the encapsulation material layer within the first isolation opening, within the third isolation opening and in the non-active area while retaining part of the light-emitting functional layer and the encapsulation material layer within the second isolation opening, to form the second light-emitting device and the second encapsulation unit that are at least partially located in the second isolation opening.

The present application also provides an electronic device, including a display panel provided in the present application, or a display panel manufactured by a method for manufacturing a display panel provided in the present application.

The present application has the following beneficial effects with respect to the prior art.

According to the display panel, the method for manufacturing a display panel, and the electronic device provided in the present application, in the display panel having at least an isolation structure, the first encapsulation layer covering the non-active area is fabricated while fabricating the light-emitting device and its corresponding encapsulation unit, and the encapsulation effect of the display panel can be guaranteed.

Furthermore, in the display panel, the method for manufacturing a display panel, and the electronic device provided in the present application, the first encapsulation layer is formed simultaneously with the third encapsulation unit corresponding to the third light-emitting device fabricated last, and it is possible to prevent the etching operation on the light-emitting device and the encapsulation unit fabricated later from affecting the first encapsulation layer in the non-active area, thereby ensuring the encapsulation reliability of the first encapsulation layer.

### BRIEF DESCRIPTION OF THE DRAWINGS

In order to illustrate the embodiments of the present application more clearly, the drawings required in the embodiments will be briefly introduced below. It should be understood that the following drawings only show some embodiments of the present application, and therefore should not be construed as a limitation on the scope.

FIG. 1 is a partial schematic diagram of a display panel according to an embodiment;

FIG. 2 is a first schematic cross-sectional view a display panel according to an embodiment;

FIG. 3 is a second schematic cross-sectional view of the display panel according to an embodiment;

FIG. 4 is a third schematic cross-sectional view of the display panel according to an embodiment;

FIG. 5 is a fourth schematic cross-sectional view of the display panel according to an embodiment;

FIG. 6 is a first schematic diagram of an isolation structure according to an embodiment;

FIG. 7 is a second schematic diagram of the isolation structure according to an embodiment;

FIG. 8 is a schematic flowchart of steps of a method for manufacturing a display panel according to an embodiment;

FIG. 9 is a first schematic diagram of a process for manufacturing a display panel according to an embodiment;

FIG. 10 is a second schematic diagram of the process for manufacturing a display panel according to an embodiment;

FIG. 11 is a third schematic diagram of the process for manufacturing a display panel according to an embodiment;

FIG. 12 is a fourth schematic diagram of the process for manufacturing a display panel according to an embodiment;

FIG. 13 is a fifth schematic diagram of the process for manufacturing a display panel according to an embodiment; and

FIG. 14 is a sixth schematic diagram of the process for manufacturing a display panel according to an embodiment.

### DETAILED DESCRIPTION OF THE EMBODIMENTS

In order to make the embodiments of the present application clearer, the embodiments of the present application will be described clearly and completely below with reference to the accompanying drawings in the embodiments of the present application. Apparently, the embodiments described are some of, rather than all of, the embodiments of the present application. In general, assemblies of the embodiments of the present application described and shown in the accompanying drawings herein can be arranged and designed in various configurations.

Thus, the following detailed description of the embodiments of the present application provided in the accompanying drawings is not intended to limit the scope of the present application as claimed, but is merely representative of the selected embodiments of the present application.

It should be noted that like items are denoted by like numerals and letters in the following drawings. Therefore, once a specific item is defined in one of the drawings, the item needs not to be further defined and explained in subsequent drawings.

In the description of the present application, it should be noted that orientations or position relationships indicated by terms such as “center,” “upper,” “lower”, “vertical”, “horizontal”, “inner”, and “outer” are based on orientations or position relationships shown in the drawings or the orientations or position relationships in which a product of the present application is customarily placed in use, and are merely intended to facilitate and simplify the description of the present application, rather than indicating or implying that the device or element considered must have a particular orientation or be constructed and operated in a particular orientation, and therefore not to be construed as limiting the present application. In addition, the terms such as “first”, “second” and “third” are merely intended to distinguish the description, and are not to be construed as indicating or implying relative importance.

It should be noted that different features in the embodiments of the present application may be combined with each other without conflicts.

In some display panels, an isolation structure having isolation openings is provided, and light-emitting devices of different colors can be formed in different isolation openings by first entire-layer evaporation and then etching. Reference can be made to relevant solutions of the isolation structure recited in patent applications PCT/CN 2023/134518, 202310759370.2, 202310740412.8, 202310707209.0, and 202311346196.5, the contents of which are incorporated herein by reference.

The inventors have found that in such display panels, in order to protect a light-emitting device during patterned etching of the light-emitting device, it is necessary to fabricate an encapsulation unit covering the light-emitting device while forming the light-emitting device by etching. However, how to ensure the encapsulation effect of the non-active area has become a problem to be solved urgently.

In view of this, this embodiment provides a solution by which the encapsulation effect of the non-active area can be improved for the display panel employing at least an isolation structure, and the solution provided in this embodiment will be elaborated below.

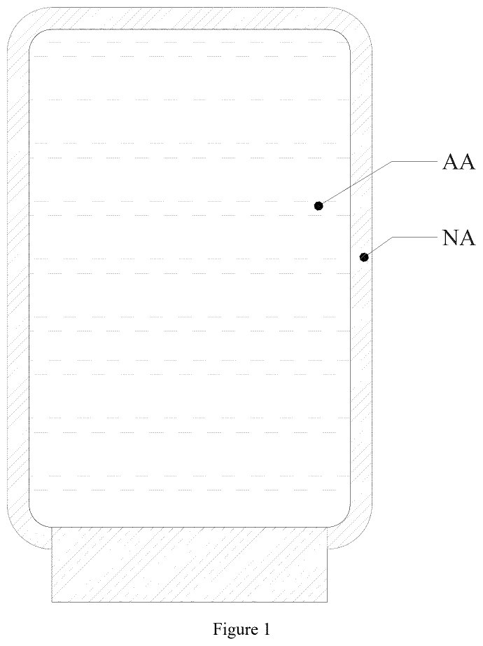

Referring to FIG. 1, this embodiment provides a display panel including an active area AA and a non-active area NA at least partially surrounding the active area AA.

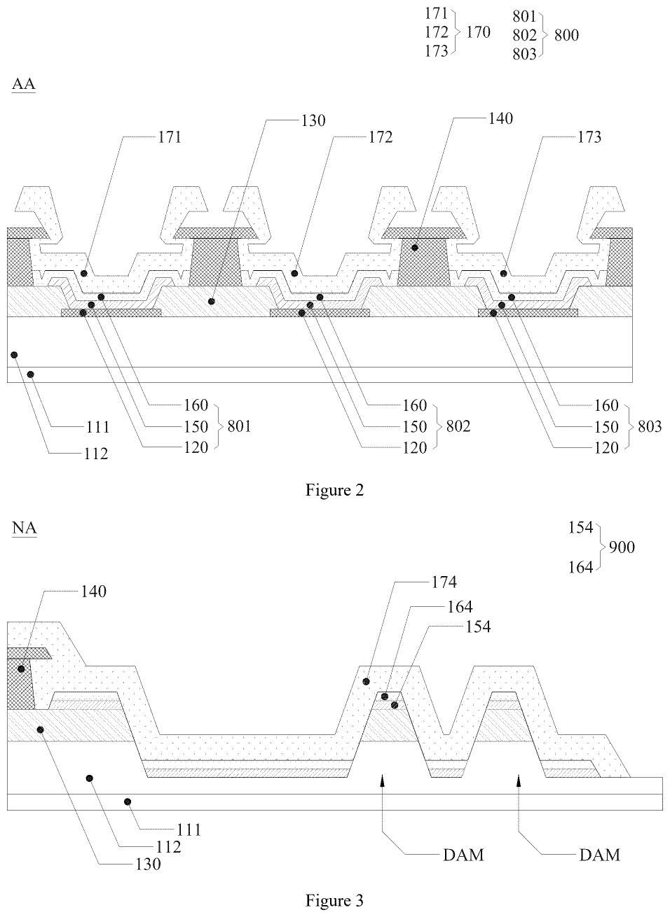

Referring to FIGS. 2 and 3, the display panel includes a substrate 111, an array functional layer 112, at least an isolation structure 140, and at least a light-emitting device 800, at least an encapsulation unit 170, a redundant light-emitting functional layer 900, and a first encapsulation layer 174.

In this embodiment, a material of the substrate 111 may include a rigid material, such as glass. Alternatively, the material of the substrate 111 may include a flexible material, such as polyimide (Pi).

The array functional layer 112 is located on one side of the substrate 111. In this embodiment, the array functional layer 112 may include a plurality of film layer structures, such as an active layer, a plurality of metal layers, a plurality of insulation layers, and a planarization layer. The plurality of film layer structures of the array functional layer 112 can form a plurality of thin film transistors (TFTs) at different locations, and the thin film transistors cooperate with each other to form a plurality of pixel drive units or pixel drive circuits.

The isolation structure 140 is located on a side of the array functional layer 112 away from the substrate 111, and at least an isolation opening is defined in the active area AA.

In an embodiment, the display panel according to this embodiment may further include a pixel defining layer 130 located between the isolation structure 140 and the array functional layer 112. The pixel defining layer 130 includes a pixel opening. An orthographic projection of the pixel opening on the substrate 111 is located within an orthographic projection of the isolation opening on the substrate 111. That is, the pixel opening is in communication with the isolation opening.

At least parts of the light-emitting device 800 and its corresponding encapsulation unit 170 are located in the isolation opening, and the encapsulation unit 170 is located on a side of the light-emitting device 800 away from the substrate 111.

In an embodiment, the light-emitting device 800 includes a first electrode 120, a light-emitting unit 150, and a second electrode 160 stacked in a direction away from the substrate 111, and the isolation structure 140 has an electrical conductivity, the second electrode 160 being electrically connected to the isolation structure 140.

The first electrode 120 may be connected to a pixel drive circuits of the array substrate, and the second electrode 160 may be connected to a common voltage supply circuit via the isolation structure 140. When there is a potential difference between the first electrode 120 and the second electrode 160, the light-emitting unit 150, which is located between the first electrode 120 and the second electrode 160, is driven to emit light. The light-emitting color of the light-emitting device 800 is the color of light emitted by the light-emitting unit 150.

The redundant light-emitting functional layer 900 and the first encapsulation layer 174 are located in the non-active area NA and on the side of the array functional layer 112 away from the substrate 111, and the redundant light-emitting functional layer 900 and the first encapsulation layer 174 are stacked in the direction away from the substrate 111.

In an embodiment, the redundant light-emitting functional layer 900 may include a redundant light-emitting material layer 154 and a redundant electrode material layer 164 stacked in the direction away from the substrate 111.

On the basis of the above design, in the display panel having the isolation structure 140, the first encapsulation layer 174 covering the non-active area NA is fabricated while fabricating the light-emitting device and its corresponding encapsulation unit 170, and the encapsulation effect of the display panel can be guaranteed.

In some embodiments, the at least a light-emitting device 800 includes a plurality of light-emitting devices 800, the plurality of light-emitting devices 800 including a first light-emitting device 801, a second light-emitting device 802, and a third light-emitting device 803. Light-emitting colors of the first light-emitting device 801, the second light-emitting device 802 and the third light-emitting device 803 are different from one another. For example, the light-emitting colors of the first light-emitting device 801, the second light-emitting device 802 and the third light-emitting device 803 each may be one of red, green and blue.

A light-emitting color of the redundant light-emitting functional layer 900 is the same as one of the light-emitting colors of the light-emitting devices 800. For example, the light-emitting color of the redundant light-emitting functional layer 900 may be one of red, green and blue. The light-emitting color of the redundant light-emitting functional layer 900 may be the color of light emitted by the material used in the redundant light-emitting material layer 154 under the condition of electroluminescence.

The at least an encapsulation unit 170 includes a plurality of encapsulation units 170. The encapsulation units 170 includes a first encapsulation unit 171 located on a side of the first light-emitting device 801 away from the substrate 111, a second encapsulation unit 172 located on a side of the second light-emitting device 802 away from the substrate 111, and a third encapsulation unit 173 located on a side of the third light-emitting device 803 away from the substrate 111.

The first encapsulation layer 174 corresponds to one of the encapsulation units 170 which has a light-emitting color same to that of the redundant light-emitting functional layer 900. That is, the first encapsulation layer 174 is fabricated simultaneously with the encapsulation unit 170 corresponding to the light-emitting device 800 of one of the light-emitting colors, the light-emitting device 800 is fabricated simultaneously with the redundant light-emitting functional layer 900, and the light-emitting color of the light-emitting device 800 is the same as the light-emitting color of the redundant light-emitting functional layer 900.

In some embodiments, the first light-emitting device 801, the second light-emitting device 802, and the third light-emitting device 803 are fabricated in sequence, the third light-emitting device 803 being the last to be fabricated, the redundant light-emitting functional layer 900 and the third light-emitting device 803 have the same light-emitting color, and the first encapsulation layer 174 is the same as the third encapsulation unit 173. That is, while the third light-emitting device 803 and the encapsulation unit 170 corresponding to the third light-emitting device 803 are fabricated, the redundant light-emitting functional layer 900 and the first encapsulation layer 174 are formed in the non-active area NA.

On the basis of the above design, in the display panel having the isolation structure 140, the first encapsulation layer 174 covering the non-active area NA is fabricated while fabricating the third light-emitting device 803 and its corresponding encapsulation unit 170, and the encapsulation effect of the display panel can be guaranteed.

In some embodiments, the degree of etch damage of the first encapsulation layer 174 and the third encapsulation unit 173 is less than the degree of etch damage of the first encapsulation unit 171 and the second encapsulation unit 172. The degree of etch damage may include roughness, pit density, pit size, crack distribution density, etc. of the surface of the encapsulation unit or the first encapsulation layer.

Specifically, in this embodiment, the first light-emitting device 801 and the second light-emitting device 802 may be fabricated before the third light-emitting device 803, and then the redundant light-emitting functional layer 900 and the first encapsulation layer 174 are formed in the non-active area while forming the third light-emitting device 803 and the third encapsulation unit 173.

In this case, after the fabrication of the third encapsulation unit 173 and the first encapsulation layer 174 is completed, etching operation is no longer performed on the encapsulation unit 170 of the other devices, and the third encapsulation unit 173 and the first encapsulation layer 174 are no longer damaged by etching, and therefore the degree of etch damage of the first encapsulation layer 174 and the third encapsulation unit 173 is less than the degree of etch damage of the first encapsulation unit 171 and the second encapsulation unit 172. In this way, the encapsulation effectiveness of the first encapsulation layer 174 in the non-active area NA can be improved.

In some embodiments, a maximum thickness of the first encapsulation layer 174 and the third encapsulation unit 173 is greater than a maximum thickness of the first encapsulation unit 171 and the second encapsulation unit 172.

Specifically, in this embodiment, the first light-emitting device 801 and the second light-emitting device 802 may be fabricated before the third light-emitting device 803, and then the redundant light-emitting functional layer 900 and the first encapsulation layer 174 are formed in the non-active area while forming the third light-emitting device 803 and the third encapsulation unit 173.

In this case, after the fabrication of the third encapsulation unit 173 and the first encapsulation layer 174 is completed, etching operation is no longer performed on the encapsulation unit 170 of the other devices, and the third encapsulation unit 173 and the first encapsulation layer 174 are no longer damaged by etching, and therefore the maximum thickness of the first encapsulation layer 174 and the third encapsulation unit 173 is greater than the maximum thickness of the first encapsulation unit 171 and the second encapsulation unit 172. In this way, the encapsulation effectiveness of the first encapsulation layer 174 in the non-active area NA can be improved.

In some embodiments, referring again to FIG. 3, in the non-active area NA, the array functional layer 112 includes a dam structure DAM protruding in the direction away from the substrate 111, the dam structure DAM at least partially surrounding the active area AA.

In one embodiment, the dam structure DAM may be formed from one or more planarization layers of the array functional layer 112. In one embodiment, part of the pixel defining layer 130 may be located on a side of the dam structure DAM away from the substrate 111.

At least parts of the redundant light-emitting functional layer 900 and the first encapsulation layer 174 are located on the side of the dam structure DAM away from the substrate 111. That is, in this embodiment, the redundant light-emitting functional layer 900 and the first encapsulation layer 174 may extend to cover the dam structure DAM.

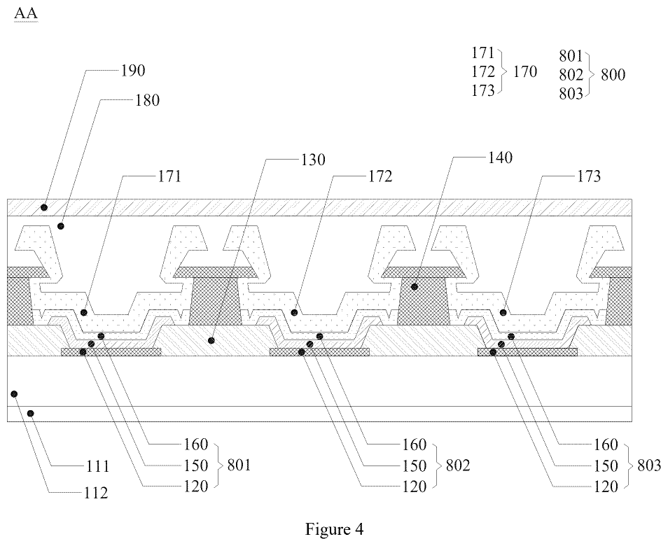

In some embodiments, referring to FIGS. 4 and 5, the display panel according to this embodiment may further include a second encapsulation layer 180 located on a side of the encapsulation unit 170 and the isolation structure 140 away from the substrate 111, and a third encapsulation layer 190 located on a side of the second encapsulation layer 180 away from the substrate 111.

An orthographic projection of the second encapsulation layer 180 on the substrate 111 is located on a side, close to the active area AA, of an orthographic projection of the dam structure DAM on the substrate 111. That is, in this embodiment, the dam structure DAM may be configured to block the second encapsulation layer 180 having fluidity during the fabrication process to limit the flow range of the second encapsulation layer.

In an embodiment, materials of the encapsulation unit 170, the first encapsulation layer 174 and the third encapsulation layer 190 include inorganic materials, and a material of the second encapsulation layer 180 includes an organic material. For example, the encapsulation unit 170, the first encapsulation layer 174 and the third encapsulation layer 190 may be formed by means of chemical vapor deposition (CVD), and the second encapsulation layer 180 may be formed by means of ink-jet printing (IJP).

In some embodiments, referring again to FIG. 5, the third encapsulation layer 190 extends from a side of the dam structure DAM close to the active area AA to a side of the dam structure DAM away from the active area AA. The first encapsulation layer 174 located on the side of the dam structure DAM away from the active area AA is in contact with the third encapsulation layer 190. In this way, on the side of the dam structure DAM away from the active area AA, the contact between the first encapsulation layer 174 and the third encapsulation layer 190 made of inorganic materials can improve the overall water-oxygen isolation effect of the encapsulation layer, to ensure the encapsulation effectiveness.

In some embodiments, referring again to FIG. 5, an orthographic projection of an end of each of the redundant light-emitting functional layer 900 and the first encapsulation layer 174 away from the active area AA on the substrate 111 is located within an orthographic projection of the third encapsulation layer 190 on the substrate 111. In this way, it is possible to ensure that the end of the redundant light-emitting functional layer 900 away from the active area AA is covered by the third encapsulation layer 190, thereby preventing water and oxygen from intruding into the active area AA along the redundant light-emitting functional layer 900.

In some embodiments, the display panel includes at least two dam structures DAM. The at least two dam structures DAM are arranged in a direction away from the active area AA. In this way, the plurality of dam structures DAM can ensure the blocking and limiting effect on the second encapsulation layer 180.

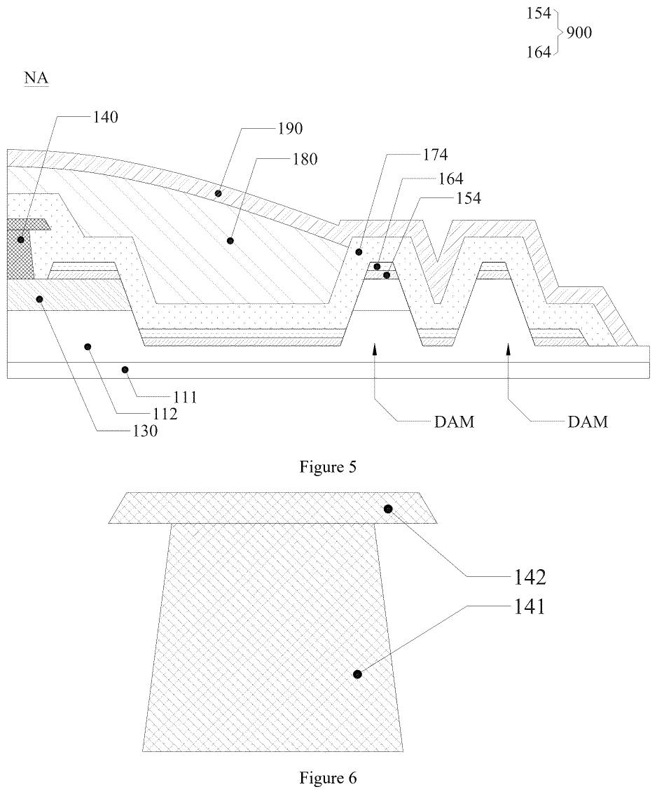

In some embodiments, referring to FIG. 6, the isolation structure 140 includes a support portion 141 and a shielding portion 142 located on a side of the support portion 141 away from the substrate 111. An orthographic projection of the support portion 141 on the substrate 111 is located within an orthographic projection of the shielding portion 142 on the substrate 111. That is, on the side close to the isolation opening, the support portion 141 is inwardly retracted relative to the shielding portion 142 to form an undercut structure.

In an embodiment, an etching resistance of the support portion 141 is weaker than an etching resistance of the shielding portion 142.

In an embodiment, a material of the support portion 141 includes aluminum, and/or a material of the shielding portion 142 includes titanium.

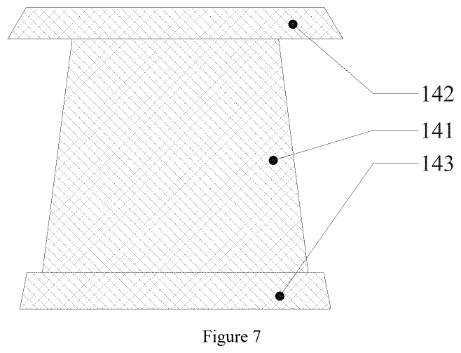

In an embodiment, referring to FIG. 7 the isolation structure 140 further includes a receiving portion 143 located between the support portion 141 and the substrate 111.

In an embodiment, an orthographic projection of the receiving portion 143 on the substrate 111 is located within the orthographic projection of the shielding portion 142 on the substrate 111.

In one embodiment, a material of the receiving portion 143 includes molybdenum.

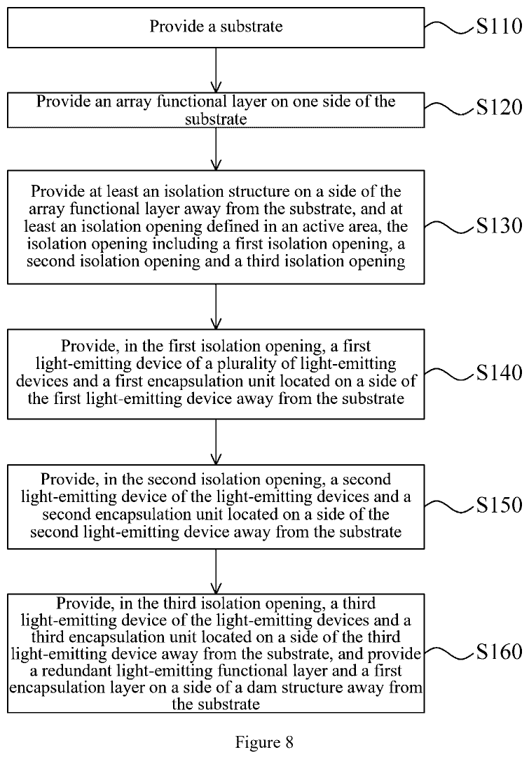

This embodiment also provides a method for manufacturing a display panel, the display panel including an active area AA and a non-active area NA at least partially surrounding the active area AA. Referring to FIG. 8, the method may include the following steps.

In step S110, a substrate 111 is provided.

In step S120, an array functional layer 112 is provided on one side of the substrate 111.

In step S130, at least an isolation structure 140 is provided on a side of the array functional layer 112 away from the substrate 111, the isolation structure 140 defining at least an isolation opening. The isolation opening includes a first isolation opening, a second isolation opening and a third isolation opening.

In step S140, a first light-emitting device 801 of a plurality of light-emitting devices and a first encapsulation unit 171 located on a side of the first light-emitting device 801 away from the substrate 111 are provided in the first isolation opening.

In step S150, a second light-emitting device 802 of the light-emitting devices and a second encapsulation unit 172 located on a side of the second light-emitting device 802 away from the substrate 111 are provided in the second isolation opening.

In step S160, a third light-emitting device 803 of the light-emitting devices and a third encapsulation unit 173 located on a side of the third light-emitting device 803 away from the substrate 111 are provided in the third isolation opening, and a redundant light-emitting functional layer 900 and a first encapsulation layer 174 are provided on a side of a dam structure DAM away from the substrate 111.

That is, in this embodiment, the first light-emitting device 801 and its corresponding first encapsulation unit 171, and the second light-emitting device 802 and its corresponding second encapsulation unit 172 are fabricated before the third light-emitting device 803 and its corresponding third encapsulation unit 173. The third encapsulation unit 173 corresponding to the third light-emitting device 803 is fabricated simultaneously with the first encapsulation layer 174. In this way, after the fabrication of the third encapsulation unit 173 and the first encapsulation layer 174 is completed, no etching operation is performed on the encapsulation unit 170 of other devices, and it is possible to prevent the etching operation on the light-emitting device 800 and the encapsulation unit 170 fabricated later from affecting the first encapsulation layer 174 in the non-active area NA, thereby ensuring the encapsulation reliability of the first encapsulation layer 174.

In some embodiments, in steps S140 and S150, the first light-emitting device 801 and its corresponding first encapsulation unit 171, and the second light-emitting device 802 and its corresponding second encapsulation unit 172 may be formed only in the first isolation opening and the second isolation opening, and there may be no light-emitting material and encapsulation material in the third isolation opening and the non-active area NA.

For example, in step S140, a full-coverage light-emitting functional layer and encapsulation material layer may be provided first from a side of the isolation structure 140 away from the substrate 111. Then, an etch stop material 700 covering the first isolation opening is provided. The light-emitting functional layer and the encapsulation material layer are then etched to remove part of the light-emitting functional layer and the encapsulation material layer within the second isolation opening, within the third isolation opening and in the non-active area NA while retaining part of the light-emitting functional layer and the encapsulation material layer within the first isolation opening, to form the first light-emitting device 801 and the first encapsulation unit 171 that are at least partially located in the first isolation opening.

In step S150, a full-coverage light-emitting functional layer and encapsulation material layer may be provided first from a side of the isolation structure 140 away from the substrate 111. Then, an etch stop material 700 covering the second isolation opening is provided. The light-emitting functional layer, an electrode material layer and the encapsulation material layer are then etched to remove part of the light-emitting functional layer and the encapsulation material layer within the first isolation opening, within the third isolation opening and in the non-active area NA while retaining part of the light-emitting functional layer and the encapsulation material layer within the second isolation opening, to form the second light-emitting device 802 and the second encapsulation unit 172 that are at least partially located in the second isolation opening.

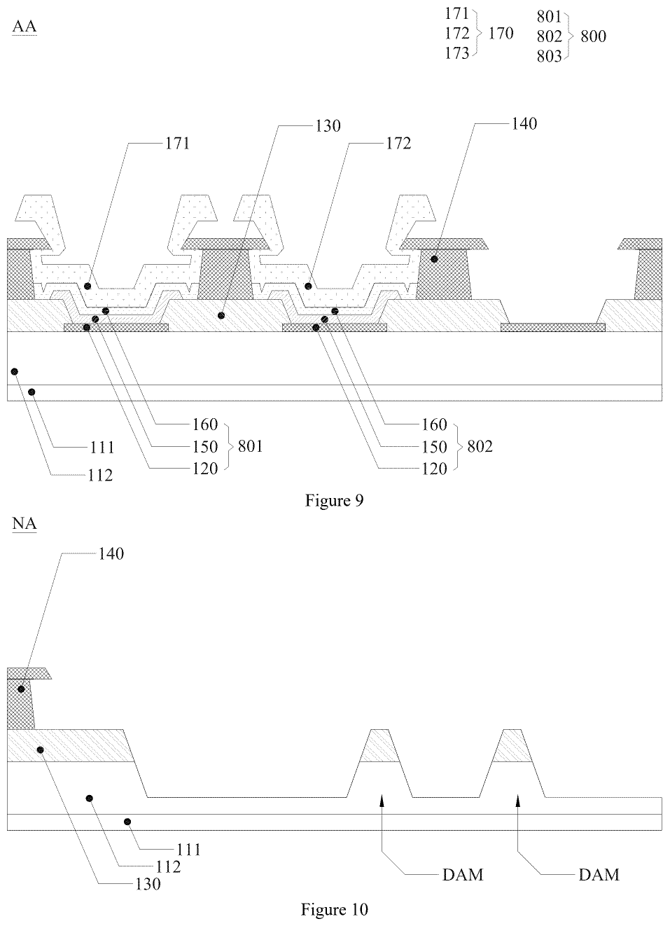

In this way, after steps S140 and S150, a structure as shown in FIGS. 9 and 10 can be formed.

In some embodiments, step S160 may include the following sub-steps.

In step S161, a full-coverage light-emitting functional layer 9001 and encapsulation material layer is provided from a side of the isolation structure 140 away from the substrate 111 1700.

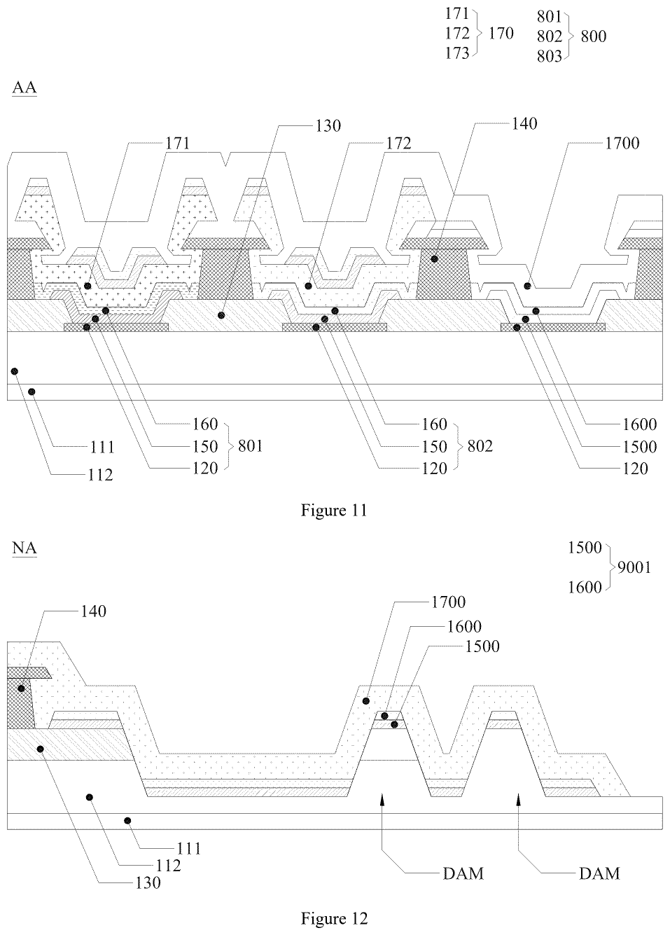

The light-emitting functional layer 9001 may include a light-emitting material layer 1500 and an electrode material layer 1600. Referring to FIGS. 11 and 12, the light-emitting functional layer 9001 and the encapsulation material layer 1700 may cover the active area AA and the non-active area NA.

In step S162, an etch stop material 700 covering the third isolation opening and the non-active area NA is provided.

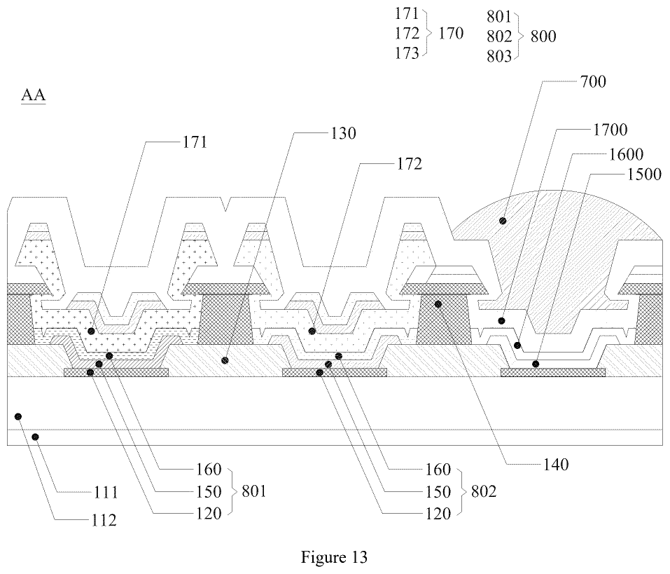

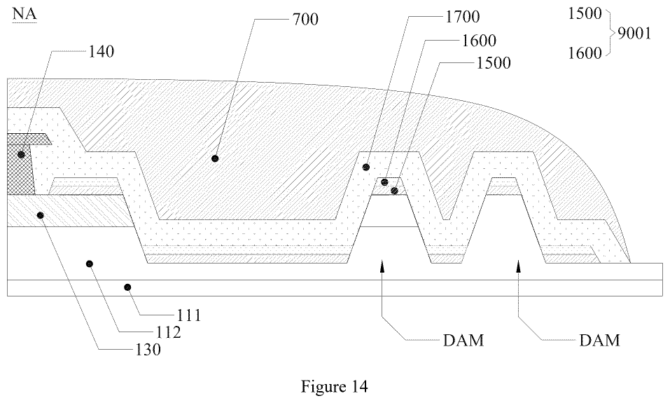

In this embodiment, referring to FIGS. 13 and 14, the etch stop material 700 may include a patterned photoresist, and the etch stop material 700 may cover the third isolation opening and the non-active area NA, and expose the first isolation opening and the second isolation opening.

In step S163, the light-emitting functional layer 9001 and the encapsulation material layer 1700 are etched to remove part of the light-emitting functional layer 9001 and the encapsulation material layer 1700 within the first isolation opening and the second isolation opening while retaining part of the light-emitting functional layer 9001 and the encapsulation material layer 1700 within the third isolation opening and in the non-active area NA, to form the third light-emitting device 803 and the third encapsulation unit 173 that are at least partially located in the third isolation opening, and the redundant light-emitting functional layer 900 and the first encapsulation layer 174 that are located in the non-active area NA.

After step S163, the structure shown in FIGS. 2 and 3 can be formed.

The present application also provides an electronic device, including a display panel provided in the present application, or a display panel manufactured by a method for manufacturing a display panel provided in the present application. The electronic device may include a device having a display function, e.g., a mobile phone, a tablet, a smart wearable device, a TV, a laptop, or a display.

In summary, according to the display panel, the method for manufacturing a display panel, and the electronic device provided in the present application, in the display panel having at least an isolation structure, the first encapsulation layer covering the non-active area is fabricated while fabricating the light-emitting device and its corresponding encapsulation unit, and the encapsulation effect of the display panel can be guaranteed.

Furthermore, in the display panel, the method for manufacturing a display panel, and the electronic device provided in the present application, the first encapsulation layer is formed simultaneously with the third encapsulation unit corresponding to the third light-emitting device fabricated last, and it is possible to prevent the etching operation on the light-emitting device and the encapsulation unit fabricated later from affecting the first encapsulation layer in the non-active area, thereby ensuring the encapsulation reliability of the first encapsulation layer.

The above embodiments may be randomly combined. To make the description concise, not all possible combinations of the above embodiments are described. However, the combinations of these features shall be considered as falling within the scope recorded in this specification provided that no conflict exists.

The above embodiments merely represent several implementations of the present application, giving specifics and details thereof, but should not be understood as limiting the scope of the present application thereby. It should be noted that various variations and improvements may without departing from the spirit of the present application and shall fall within the scope of protection of the present application. Therefore, the scope of protection of the present application shall be in accordance with the appended claims.

1. A display panel, comprising an active area and a non-active area at least partially surrounding the active area, and comprising:
a substrate;
an array functional layer located on one side of the substrate;
at least an isolation structure located on a side of the array functional layer away from the substrate;
at least an isolation opening defined in the active area;
at least a light-emitting device and at least a corresponding encapsulation unit, which are at least partially located in the isolation opening, the encapsulation unit being located on a side of the light-emitting device away from the substrate; and
a redundant light-emitting functional layer and a first encapsulation layer, which are stacked in the non-active area and on the side of the array functional layer away from the substrate.

2. The display panel according to claim 1, wherein the at least a light-emitting device comprises a plurality of light-emitting devices, the plurality of light-emitting devices comprising a first light-emitting device, a second light-emitting device and a third light-emitting device, light-emitting colors of the first light-emitting device, the second light-emitting device and the third light-emitting device being different from one another, and a light-emitting color of the redundant light-emitting functional layer being the same as one of the light-emitting colors of the light-emitting devices; and
the at least an encapsulation unit comprises a plurality of encapsulation units, the encapsulation units comprising a first encapsulation unit located on a side of the first light-emitting device away from the substrate, a second encapsulation unit located on a side of the second light-emitting device away from the substrate, and a third encapsulation unit located on a side of the third light-emitting device away from the substrate, and the first encapsulation layer corresponding to one of the encapsulation units which has a light-emitting color same to that of the redundant light-emitting functional layer.

3. The display panel according to claim 2, wherein the first encapsulation layer is fabricated simultaneously with one of the encapsulation units which has a light-emitting color same to that of the redundant light-emitting functional layer.

4. The display panel according to claim 2, wherein the first light-emitting device, the second light-emitting device, and the third light-emitting device are fabricated in sequence, the third light-emitting device being the last to be fabricated, the redundant light-emitting functional layer and the third light-emitting device have the same light-emitting color, and the first encapsulation layer is the same as the third encapsulation unit.

5. The display panel according to claim 4, wherein a maximum thickness of the first encapsulation layer and the third encapsulation unit is greater than a maximum thickness of the first encapsulation unit and the second encapsulation unit.

6. The display panel according to claim 1, wherein in the non-active area, the array functional layer comprises a dam structure protruding in a direction away from the substrate, the dam structure at least partially surrounding the active area; and
at least parts of the redundant light-emitting functional layer and the first encapsulation layer are located on a side of the dam structure away from the substrate.

7. The display panel according to claim 6, further comprising a second encapsulation layer located on a side of the encapsulation unit and the isolation structure away from the substrate, and a third encapsulation layer located on a side of the second encapsulation layer away from the substrate.

8. The display panel according to claim 7, wherein an orthographic projection of the second encapsulation layer on the substrate is located on a side, close to the active area, of an orthographic projection of the dam structure on the substrate.

9. The display panel according to claim 6, wherein the third encapsulation layer extends from a side of the dam structure close to the active area to a side of the dam structure away from the active area; and
the first encapsulation layer located on the side of the dam structure away from the active area is in contact with the third encapsulation layer.

10. The display panel according to claim 9, wherein an orthographic projection of an end of each of the redundant light-emitting functional layer and the first encapsulation layer away from the active area on the substrate is located within an orthographic projection of the third encapsulation layer on the substrate.

11. The display panel according to claim 6, comprising at least two dam structures arranged in a direction away from the active area.

12. The display panel according to claim 1, wherein the light-emitting device comprises a first electrode, a light-emitting unit and a second electrode stacked in a direction away from the substrate, and the isolation structure has an electrical conductivity, the second electrode being electrically connected to the isolation structure.

13. The display panel according to claim 1, wherein the isolation structure comprises a support portion and a shielding portion located on a side of the support portion away from the substrate, an orthographic projection of the support portion on the substrate being located within an orthographic projection of the shielding portion on the substrate.

14. The display panel according to claim 13, wherein an etching resistance of the support portion is weaker than an etching resistance of the shielding portion.

15. The display panel according to claim 13, wherein the isolation structure further comprises a receiving portion located between the support portion and the substrate.

16. The display panel according to claim 15, wherein an orthographic projection of the receiving portion on the substrate is located within the orthographic projection of the shielding portion on the substrate.

17. A method for manufacturing a display panel, the display panel comprising an active area and a non-active area at least partially surrounding the active area, the method comprising:
providing a substrate;
providing an array functional layer on one side of the substrate;
providing at least an isolation structure on a side of the array functional layer away from the substrate, and at least an isolation opening defined in the active area, the isolation opening comprising a first isolation opening, a second isolation opening and a third isolation opening;
providing, in the first isolation opening, a first light-emitting device of a plurality of light-emitting devices and a first encapsulation unit located on a side of the first light-emitting device away from the substrate;
providing, in the second isolation opening, a second light-emitting device of the plurality of light-emitting devices and a second encapsulation unit located on a side of the second light-emitting device away from the substrate; and
providing, in the third isolation opening, a third light-emitting device of the plurality of light-emitting devices and a third encapsulation unit located on a side of the third light-emitting device away from the substrate, and
providing a redundant light-emitting functional layer and a first encapsulation layer on a side of the dam structure away from the substrate.

18. The method for manufacturing a display panel according to claim 17, wherein the step of providing, in the third isolation opening, a third light-emitting device of the light-emitting devices and a third encapsulation unit located on a side of the third light-emitting device away from the substrate, and providing a redundant light-emitting functional layer and a first encapsulation layer on a side of the dam structure away from the substrate comprises:
providing a full-coverage light-emitting functional layer and encapsulation material layer from a side of the isolation structure away from the substrate;
providing an etch stop material covering the third isolation opening and the non-active area; and
etching the light-emitting functional layer and the encapsulation material layer, to remove part of the light-emitting functional layer and the encapsulation material layer within the first isolation opening and the second isolation opening, while retaining part of the light-emitting functional layer and the encapsulation material layer within the third isolation opening and in the non-active area, to form the third light-emitting device and the third encapsulation unit that are at least partially located in the third isolation opening, and the redundant light-emitting functional layer and the first encapsulation layer that are located in the non-active area.

19. The method for manufacturing a display panel according to claim 17, wherein the step of providing, in the first isolation opening, a first light-emitting device and a first encapsulation unit located on a side of the first light-emitting device away from the substrate comprises:
providing a full-coverage light-emitting functional layer and encapsulation material layer from a side of the isolation structure away from the substrate;
providing an etch stop material covering the first isolation opening; and
etching the light-emitting functional layer and the encapsulation material layer, to remove part of the light-emitting functional layer and the encapsulation material layer within the second isolation opening, within the third isolation opening and in the non-active area, while retaining the light-emitting functional layer and the encapsulation material layer within the first isolation opening, to form the first light-emitting device and the first encapsulation unit that are at least partially located in the first isolation opening; and
the step of providing, in the second isolation opening, a second light-emitting device and a second encapsulation unit located on a side of the second light-emitting device away from the substrate comprises:
providing a full-coverage light-emitting functional layer and encapsulation material layer from a side of the isolation structure away from the substrate;
providing an etch stop material covering the second isolation opening; and
etching the light-emitting functional layer and the encapsulation material layer, to remove part of the light-emitting functional layer and the encapsulation material layer within the first isolation opening, within the third isolation opening and in the non-active area, while retaining part of the light-emitting functional layer and the encapsulation material layer within the second isolation opening, to form the second light-emitting device and the second encapsulation unit that are at least partially located in the second isolation opening.

20. An electronic device, comprising:
a display panel, comprising an active area and a non-active area at least partially surrounding the active area, and comprising:
a substrate;
an array functional layer located on one side of the substrate;
at least an isolation structure located on a side of the array functional layer away from the substrate;
at least an isolation opening defined in the active area;
at least a light-emitting device and at least a corresponding encapsulation unit, which are at least partially located in the isolation opening, the encapsulation unit being located on a side of the light-emitting device away from the substrate; and
a redundant light-emitting functional layer and a first encapsulation layer, which are stacked in the non-active area and on the side of the array functional layer away from the substrate.
